(19) United States
(12) Patent Application Publication
(10) Pub. No.: US 2026/0210778 A1
(43) Pub. Date: Jul. 23, 2026

(54) MEASUREMENT SYSTEM

(71) Applicant: TOPOLOGIC INC., Tokyo (JP)

(72) Inventor: Arata TAKAHASHI, Tokyo (JP)

(21) Appl. No.: 19/142,852

(22) PCT Filed: Dec. 25, 2023
(86) PCT No.: PCT/JP2023/046313

§ 371 Date: Jun. 24, 2025

(30) Foreign Application Priority Data
Dec. 28, 2022 (JP) 2022-212371

(51) Int. Cl. G01K 17/04; G01K 1/08; G01K 1/16; H10N 15/00; H10N 19/00

(52) U.S. Cl. CPC G01K 17/04; G01K 1/08; G01K 1/16; H10N 15/00; H10N 19/00

(57) ABSTRACT

According to an aspect of the present invention, a measurement system is provided. This measurement system comprises a heat flow sensor and a housing. The heat flow sensor includes a substrate having electrical insulation and a thermoelectric conversion unit provided on the substrate. The thermoelectric conversion unit is configured to generate an electromotive force on the basis of a temperature gradient along a gradient direction towards the thermoelectric conversion unit from the substrate. The housing is configured to be capable of accepting the heat flow sensor and includes a first wall and a second wall. The first wall is configured to face the substrate. The second wall is configured to cover the heat flow sensor by extending along the gradient direction from the first wall and includes an opening. The opening is configured to pass through the second wall so that at least a portion of the thermoelectric conversion unit is continuous with the outside of the housing without passing through the substrate.

### CROSS REFERENCE TO RELATED APPLICATIONS

This application is a 371 U.S. National Phase of International Application No. PCT/JP2023/046313, filed on Dec. 25, 2023, which claims priority to Japanese Patent Application No. 2022-212371, filed Dec. 28, 2022. The entire disclosures of the above applications are incorporated herein by reference.

### BACKGROUND

Technical Field

The present invention relates to a measuring system.

### Background Art

Japanese Unexamined Patent Application Publication No. 2019-132802 discloses a technology related to a heat flux sensor capable of accurately measuring the amount of the physiological heat of a person to be measured while suppressing discomfort of the person to be measured.

This heat flux sensor for measuring the amount of heat emitted from a human body or a heat flux received by a human body includes a porous film and a thermocouple array circuit. The porous film is formed in the shape of a thin sheet and has a continuous pore porous structure in which a large number of pores are continuously connected to each other from one surface to the other surface in the thickness direction. The thermocouple array circuit is disposed inside the porous film and outputs a sensor signal corresponding to a heat flux passing through the porous film in the thickness direction.

There is still room for improvement in the technology for practically incorporating a thermoelectric conversion unit such as the above heat flux sensor into a measuring system.

### SUMMARY

According to one aspect of the present invention, a measuring system is provided. This measuring system includes a heat flow sensor and a housing. The heat flow sensor includes a substrate having electrical insulation properties and a thermoelectric conversion unit disposed on the substrate. The thermoelectric conversion unit is configured to generate an electromotive force on the basis of a temperature gradient along a gradient direction that is a direction from the substrate toward the thermoelectric conversion unit. The housing houses the heat flow sensor and includes a first wall and a second wall. The first wall faces the substrate. The second wall extends along the gradient direction from the first wall to cover the heat flow sensor and has an opening. The opening penetrates the second wall so that at least a portion of the thermoelectric conversion unit communicates with outside of the housing not through the substrate.

Such a configuration can promote practical use of measuring systems including a thermoelectric conversion unit.

### BRIEF DESCRIPTION OF THE DRAWINGS

FIG. 1 is a side cross-sectional view from a y-axis direction of an example configuration of a measuring system 1.

FIG. 2 is a plan view from a z-axis direction of the example configuration of the measuring system 1 shown in FIG. 1.

FIG. 3 is a diagram showing an example configuration of a thermoelectric conversion unit 33.

FIG. 4 is a diagram showing an example configuration of a heat flow sensor 3 including multiple thermoelectric conversion units 33.

FIG. 5 is a diagram showing another example of the measuring system 1.

FIG. 6 is a plan view from the z-axis direction of a coil layer 4 incorporated in the heat flow sensor 3.

FIG. 7 is a diagram showing the configuration of another example of the measuring system 1.

FIG. 8 is a diagram showing the configuration of another example of the measuring system 1.

FIG. 9 is a diagram showing another example of the measuring system 1 shown in FIG. 8.

FIG. 10 is a diagram showing an example of the measuring system 1 including magnetic field application units.

FIG. 11 is a diagram showing an example configuration of the measuring system 1.

FIG. 12 is a diagram showing an example configuration of the measuring system 1 including an optical filter 71 as a filter 7.

FIG. 13 is a diagram showing an example configuration of the measuring system 1.

### DETAILED DESCRIPTION

Now, a preferred embodiment of the present disclosure will be described in detail with reference to the accompanying drawings. In the present specification and drawings, components having substantially the same functional configuration are given the same reference signs and will not repeatedly be described.

A program to implement software in the present embodiment may be provided as a computer-readable non-transitory storage medium, or may be provided by download from an external server. The program may also be provided such that it is run on an external computer and its functions are implemented on a client terminal (so-called cloud computing).

The term “unit” in the present embodiment includes, for example, a combination of hardware resources implemented by a circuit in a broad sense and software information processing that can be specifically performed by the hardware resources. Various types of information handled in the present embodiment are represented by, for example, the physical values of signal values representing voltages or currents, high or low signal values as binary bit sets consisting of 0s or 1s, or quantum superpositions (so-called qubits) and can be transmitted and subjected to a calculation on a circuit in a broad sense.

The term “circuit in a broad sense” refers to a circuit implemented by combining at least a circuit, circuitry, a processor, memory, and the like appropriately.

Specifically, the term “circuit in a broad sense” includes an application-specific integrated circuit (ASIC), programmable logic devices (e.g., a simple programmable logic device (SPLD), a complex programmable logic device (CPLD), a field programmable gate array (FPGA)), and the like.

### 1. Example Configuration of Measuring System 1

This section describes an example configuration of a measuring system 1 according to the present embodiment. The measuring system 1 is configured to measure a heat flow in a z-axis direction by generating an electromotive force on the basis of a temperature gradient in the z-axis direction. As will be described later, the z-axis direction is an example of a gradient direction. For convenience's sake, two directions in a plane perpendicular to the z-axis direction are referred to as an x-axis direction and a y-axis direction. The x-axis, y-axis, and z-axis directions are perpendicular to each other to form a Cartesian coordinate system. A plane defined by the x-axis and y-axis directions may be referred to as the xy-plane.

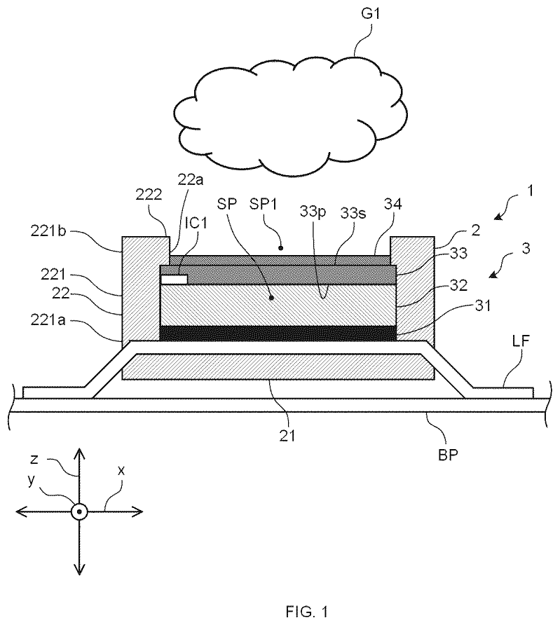

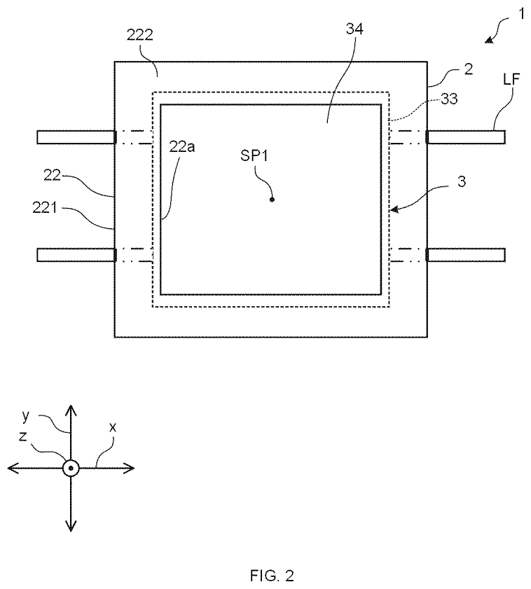

FIG. 1 is a side cross-sectional view from the y-axis direction of an example configuration of the measuring system 1. FIG. 2 is a plan view from the z-axis direction of the example configuration of the measuring system 1 shown in FIG. 1. The scale, the positional relationship, and the like are only illustrative, and these are not limiting. As shown in FIGS. 1 and 2, the measuring system 1 includes a housing 2 and a heat flow sensor 3.

### <Housing 2>

The housing 2 houses the heat flow sensor 3 (to be discussed later). Although the housing 2 may be made of any material, it is preferably made of a material having relatively low thermal resistance and heat capacity so that it can transfer heat to the heat flow sensor 3 with a short delay. For example, the material of the housing 2 may be a metal, carbon, or the like. The housing 2 according to the present embodiment includes a first wall 21 and a second wall 22.

### <First Wall 21>

The first wall 21 is a wall that forms the bottom of the housing. The first wall 21 extends in a plane having the z-axis direction as the normal direction, i.e., in the xy-plane. The first wall 21 may be formed in any shape. In the present embodiment, it is formed in the shape of a flat plate, for example, a square flat plate.

### <Second Wall 22>

The second wall 22 extends along the gradient direction from the first wall 21. Thus, the first wall 21 and second wall 22 form a housing space SP that can house the heat flow sensor 3 (to be discussed later). For example, at least a portion of the second wall 22 faces the first wall 21 in the z-axis direction to cover the housing space SP. The second wall 22 has an opening 22a. The opening 22a penetrates the second wall 22. Thus, the housing space SP communicates with the outside of the housing 2.

Specifically, for example, the second wall 22 may include a peripheral wall 221. In the present embodiment, the second wall 22 further may include an end wall 222.

### <Peripheral Wall 221>

The peripheral wall 221 extends along the z-axis direction as the gradient direction from the outer edge of the first wall 21. In the present embodiment, the peripheral wall 221 is formed in the shape of a square tube extending along the z-axis direction from the outer edge of the first wall 21. Thus, the inner surface of the peripheral wall 221 forms the sidewall of the housing space SP. For convenience's sake, of the ends of the peripheral wall 221, an end connected to the first wall 21 is referred to as a first end 221a, and an end opposite to the first end is referred to as a second end 221b.

### <End Wall 222>

The end wall 222 is connected to the end (i.e., the second end 221b) different from the end connected to the first wall 21 (i.e., the first end 221a) of the ends of the peripheral wall 221. In the present embodiment, the end wall 222 extends from the second end 221b toward the center of the first wall 21 in the xy plane. Thus, the end wall 222 faces at least a portion of the first wall 21 in the z-axis direction.

<Opening 22a>

In the present embodiment, the opening 22a is formed in the end wall 222. For example, the end wall 222 extends toward the center of the first wall 21 in the xy plane such that an opening formed by the second end 221b in the z-axis direction is not blocked. Thus, in the present embodiment, an opening space SP1 having a shape along the outer edge of the first wall 21 is formed as a through hole in the center of the end wall 222. The inner circumferential surface of the end wall 222 defining the opening space SP1 corresponds to the opening 22a. In other words, the opening 22a penetrates the housing 2 (the second wall 22 in the present embodiment) along the z-axis direction. Such a configuration facilitates the transfer of heat in the z-axis direction as the gradient direction and further improves the stability of the electromotive force from the heat flow sensor 3.

### <Heat Flow Sensor 3>

The heat flow sensor 3 is housed inside the above housing 2. The heat flow sensor 3 includes a bonding layer 31, a substrate 32, and a thermoelectric conversion unit 33. The heat flow sensor 3 may further include a catalyst layer 34.

### <Bonding Layer 31>

The bonding layer 31 is a layer for bonding the member to the first wall 21. Although the bonding layer 31 may be made of any material, it is preferably made of a material having relatively low thermal resistance and heat capacity.

The substrate 32 has electrical insulation properties. Preferably, the substrate 32 is rigid against an external force along the z-axis direction in terms of the durability in the housing 2. In the present embodiment, the substrate 32 is formed in the shape of a flat plate having the z-axis direction as the normal direction. The substrate 32 may take any form. For example, the substrate 32 may be a chip that incorporates an LSI (large-scale integrated circuit) made of Si or the like, or may be an insulating film made of polyamide or the like, a flexible circuit board, a printed circuit board, a sapphire substrate, an Al board, a Cu board, an MgO board, or a substrate made of GaN, SiC, SiO₂/Si, Ta₂)₅/Ta, Al₂O₃, Al₂O₃/Al, SiN, Ti, TiO₂/Ti, CuO/Cu, Ga₂O₃, GaAs, InAs, InSb, or the like or a composite or the like thereof and having good thermal conductivity on which an IC is mounted, or may be any combination thereof. The substrate 32 is bonded to the first wall 21 through the bonding layer 31. Thus, the first wall 21 faces the substrate 32 through the bonding layer 31 in the z-axis direction. Note that the first wall 21 may be formed to directly face the substrate 32 not through the bonding layer 31. In other words, whether the bonding layer 31 is provided is optional.

### <Thermoelectric Conversion Unit 33>

The thermoelectric conversion unit 33 is configured to generate an electromotive force on the basis of a temperature gradient along the z-axis direction. For example, the thermoelectric conversion unit 33 is configured to generate an electromotive force on the basis of the anomalous Nernst effect. Such a configuration makes the size of the measuring system 1 in the gradient direction more compact than that of a measuring system using Seebeck elements. Note that at least a portion of the thermoelectric conversion unit 33 may be configured to generate an electromotive force on the basis of the Seebeck effect.

The thermoelectric conversion unit 33 is disposed over the substrate 32 in the z-axis direction. The z-axis direction is an example of the gradient direction due to it being a direction from the substrate 32 toward the thermoelectric conversion unit 33. Specifically, the thermoelectric conversion unit 33 is disposed on a surface opposite to a surface connected to the first wall 21 of the substrate 32. Thus, the first wall 21 is configured to exchange heat with the thermoelectric conversion unit 33 through the substrate 32.

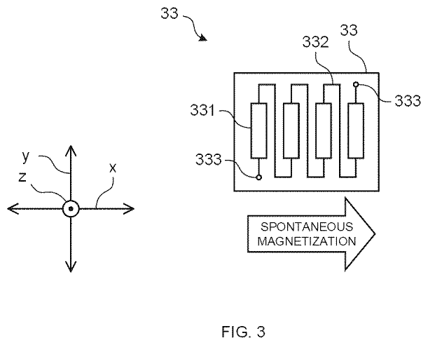

An example configuration of the thermoelectric conversion unit 33 will be described below. FIG. 3 is a diagram showing an example configuration of the thermoelectric conversion unit 33. As shown in FIG. 3, the thermoelectric conversion unit 33 includes multiple thermoelectric conversion elements 331, wiring 332, and a pair of output terminals 333.

### <Thermoelectric Conversion Element 331>

The thermoelectric conversion elements 331 are configured to generate an electromotive force due to the temperature gradient in the z-axis direction (in other words, heat transfer) on the basis of a thermoelectric effect. The thermoelectric conversion elements 331 extend along the y-axis direction. The thermoelectric conversion elements 331 are spontaneously magnetized in a direction (the x-axis direction in the present embodiment) different from the z-axis direction as the gradient direction and thus are configured to generate an electromotive force in an in-plane direction on the basis of the above temperature gradient. For example, the thermoelectric conversion elements 331 may be formed in the shape of a thin film. The thermoelectric conversion unit 33 may include a magnetic domain configured to be magnetized along the x-axis direction, which is one of the in-plane directions of the thin films. The thermoelectric conversion elements 331 may be formed in bulk. The material of the thermoelectric conversion elements 331 may be, for example, a topological ferromagnetic or topological antiferromagnetic material called Weyl semimetal, a ferrimagnetic material, or a combination of these. These specific materials will be described later.

### <Wiring 332>

The wiring 332 connects the thermoelectric conversion elements 331 in series such that the polarities thereof are aligned.

### <Output Terminal 333>

The output terminals 333 are terminals configured to output the sum of the electromotive forces outputted from the thermoelectric conversion elements 331. The output terminals 333 do not have to be mounted as actual connection terminals but may be virtual terminals connected to an external device. In the present embodiment, the thermoelectric conversion unit 33 includes a pair of output terminals 333, and the total electromotive force V1, which is the sum of the electromotive forces of the thermoelectric conversion elements 331, is outputted from the pair of output terminals 333. In the present embodiment, the thermoelectric conversion unit 33 outputs the total electromotive force V1 based on the heat flow associated with the temperature gradient from the output terminals 333. Ideally, V1=n×k×M×Q (where k represents a proportional constant, M represents the magnetization of the thermoelectric conversion elements 331, Q represents the amount of heat transferred, and n represents the number of thermoelectric conversion elements 331 connected in series). The direction of heat transfer corresponds to the temperature gradient. The thermoelectric conversion elements 331 included in the thermoelectric conversion unit 33 have the same polarity.

For convenience's sake, of the surfaces of the thermoelectric conversion unit 33, a surface stacked on the substrate 32 is referred to as a first surface 33p, and a surface opposite to the first surface 33p in the z-axis direction (in other words, the gradient direction) is referred to as a second surface 33s (see FIG. 1). The first surface 33p and second surface 33s can be defined by areas through which heat flows into or out of the thermoelectric conversion elements 331 from or into other members. The thermoelectric conversion unit 33 generates an electromotive force on the basis of heat transfer between the first surface 33p and the second surface 33s. An insulating film (not shown) may be stacked on the second surface 33S.

### <Catalyst Layer 34>

As shown in FIGS. 1 and 2, the catalyst layer 34 is an example of an interaction portion and is configured to absorb or emit heat on the basis of a change in its bonding state caused when contacted by target particles and to exchange the absorbed or emitted heat with the thermoelectric conversion unit 33. For example, the catalyst layer 34 is configured to, when activated, change the amount of heat to be exchanged, to the degree of interaction caused by contact with the target particles contained in a gas G1. In the present embodiment, the catalyst layer 34 is configured to, when the target particles contained in the gas G1 are adsorbed on the surface or inside of the catalyst layer 34, change the state of the target particles. If the target particles are hydrogen molecules, the catalyst layer 34 contains, for example, a Pt metal. The interaction portion does not have to be made of a catalyst such as the catalyst layer 34 but may be made of any material as long as it interacts with the target particles contained in the gas G1. For example, the interaction portion may be made of a material that adsorbs the target particles, such as a hydrogen storage alloy.

The catalyst layer 34 as the interaction portion may be configured to selectively absorb external electromagnetic radiation (e.g., visible light or infrared light). When the catalyst layer 34 thus configured absorbs light, it changes in temperature, resulting in a change in the amount of heat transferred in the thermoelectric conversion unit 33 and a change in the electromotive force. For this reason, the measuring system 1 can be made to function as an electromagnetic radiation measuring system.

The catalyst layer 34 is stacked on the second surface 33s of the thermoelectric conversion unit 33 such that it faces the substrate 32 in the z-axis direction through the thermoelectric conversion unit 33. This allows the thermoelectric conversion unit 33 to directly exchange heat with the catalyst layer 34 not through a rigid member such as the substrate 32. In the present embodiment, the catalyst layer 34 may be formed to cover the entire opening 22a and may be configured to exchange heat with the heat flow sensor 3 through an insulating film (not shown). Note that the catalyst layer 34 is not an essential component.

As shown in FIG. 2, the heat flow sensor 3 according to the present embodiment is disposed over the entire first wall 21 forming the housing space SP. Thus, the second wall 22 covers the heat flow sensor 3 in the housing space SP. The opening 22a is formed such that at least a portion of the thermoelectric conversion unit 33 communicates with the outside of the housing 2 not through the substrate 32. Such a configuration allows heat accumulated inside the housing 2 to escape through the opening 22a, thereby improving the stability of the electromotive force generated on the basis of heat exchange with the outside. The opening 22a overlaps at least a portion of the thermoelectric conversion unit 33 when the thermoelectric conversion unit 33 is seen in a plan view from the z-axis direction as the gradient direction. According to such a configuration, thermal convection promotes the contact between the thermoelectric conversion unit 33 and the outside air. In the present embodiment, the opening 22a is included in the outer edge of the heat flow sensor 3. The end wall 222 defining the opening 22a covers a portion of the thermoelectric conversion unit 33 not through the substrate 32 or a substrate different from the substrate 32. According to such a configuration, heat exchange through the opening 22a by the thermoelectric conversion unit 33 is performed not through the substrate 32 or the like. This improves the efficiency of heat transfer from the outside to the thermoelectric conversion unit 33, thereby increasing the response speed of the measuring system 1. The term “different substrate” refers to a member that can function as a substrate, for example, a member made of the material used in the above substrate 32 and, in particular, refers to a rigid bulk member. The term “substrate” does not include a member that can maintain its shape by relying on another member, for example, a thin film laminated on a substrate. In the present embodiment, the catalyst layer 34 is exposed through the opening 22a when the thermoelectric conversion unit 33 is seen in a plan view from the z-axis direction as the gradient direction. When the catalyst layer 34 thus configured takes in the outside air through the opening 22a, the target particles contained in the outside air and the catalyst layer 34 react with each other. For this reason, a quantity related to the reaction of the target particles can be obtained as the electromotive force on the basis of the resulting heat of reaction. The catalyst layer 34 may be exposed to the outside by disposing it inside the opening space SP1 defined by the opening 22a. Such a configuration suppresses degradation of the catalyst layer 34 that can be caused by interference with an external element by the catalyst layer 34.

As shown in FIG. 1, the measuring system 1 may further include an integrated circuit IC1 configured to acquire the electromotive force from the heat flow sensor 3. The integrated circuit IC1 is configured to perform predetermined signal processing on the basis of at least the electromotive force outputted from the thermoelectric conversion unit 33. In the present embodiment, the integrated circuit IC1 is disposed on the substrate 32 together with the thermoelectric conversion unit 33. Such a configuration allows the measuring system 1 to perform a series of processes from generation of the electromotive force by the thermoelectric conversion unit 33 to signal processing. The integrated circuit IC1 may be incorporated into the substrate 32 as an assembly. In other words, the substrate 32 may be a large-scale integrated circuit (LSI) containing the integrated circuit IC1.

An example of the hardware configuration of the integrated circuit IC1 will be described. The integrated circuit IC1 includes, for example, a communication unit, a storage unit, and a processor, and these components are electrically connected through a communication bus inside the integrated circuit IC1.

While the communication unit preferably uses wired communication means such as USB, IEEE 1394, Thunderbolt®, or wired LAN network communication, it may use wireless LAN network communication, mobile communication such as 3G, LTE, or 5G, BLUETOOTH® communication, or the like as necessary. Preferably, the communication unit 41 is able to use a set of these multiple communication means. Thus, the integrated circuit IC1 can transmit and receive various types of information to and from the outside through the communication unit 41 and any network.

The storage unit is storing various types of information defined by the above description. The storage unit may be embodied, for example, as a storage device such as a solid-state drive (SSD) for storing various programs or the like related to the measuring system 1 executed by the processor, or as memory such as random access memory (RAM) for storing temporarily required information (arguments, arrays, etc.) related to program calculations. The storage unit is storing various programs, variables, and the like related to the integrated circuit IC1 executed by the processor.

The processor processes and controls the overall operation related to the measuring system 1. The processor 43 is, for example, a central processing unit (CPU) (not shown). The processor implements various functions related to the measuring system 1 by reading a predetermined program stored in the storage unit. That is, when information processing by software stored in the storage unit is specifically executed by the processor, which is an example of hardware, functional units included in the processor are implemented. These will be described in more detail in the next section. Note that the processor does not have to be a single processor but may include function-specific multiple processors. Or, the processor may be a combination of these. The integrated circuit IC1 may consist of the processor alone. The integrated circuit IC1 does not have to be a digital circuit including the processor but may be an analog circuit.

### <Lead Frame LF>

As shown in FIGS. 1 and 2, the measuring system 1 further includes a lead frame LF as a conductor. The lead frame LF is electrically connected to the thermoelectric conversion unit 33 through the substrate 32 and penetrates the peripheral wall 221. The lead frame LF thus formed is able to transfer the electromotive force from the heat flow sensor 3 to the outside of the housing 2. Such a configuration makes the thickness of the measuring system 1 in the gradient direction smaller. For example, at least a portion of the lead frame LF is exposed to the outside of the housing 2. The ends of the lead frame LF located outside the housing 2 are connected to a wiring board BP. The wiring board BP is a board on which an arbitrary circuit pattern is written. Signals transmitted from the ends of the lead frame LF are transmitted to various devices through the circuit pattern written on the wiring board BP. The lead frame LF does not have to transfer the electromotive force from the heat flow sensor 3 but may be configured to transmit signals resulting from processing of the electromotive force from the heat flow sensor 3 by the above integrated circuit IC1.

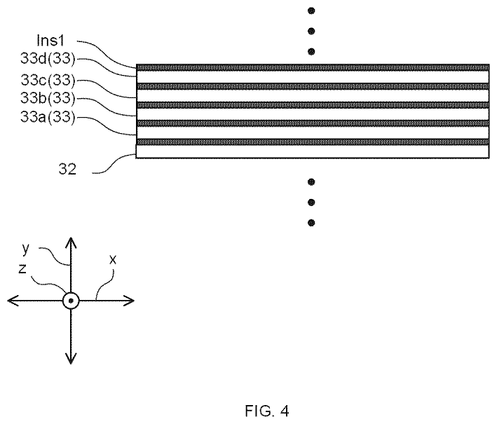

The heat flow sensor 3 may include multiple thermoelectric conversion units 33. FIG. 4 is a diagram showing an example configuration of a heat flow sensor 3 including multiple thermoelectric conversion units 33. The same components as the above components are given the same numbers and therefore the description thereof may be omitted.

As shown in FIG. 4, in the present embodiment, the heat flow sensor 3 includes four thermoelectric conversion units 33a to 33d as multiple thermoelectric conversion units 33 and insulating films Ins1 having electrical insulation properties. As with the above thermoelectric conversion unit 33 described with reference to FIG. 3, the thermoelectric conversion units 33a to 33d each include multiple thermoelectric conversion elements 331, wiring 332, and output terminals 333. The thermoelectric conversion units 33a to 33d are sequentially layered on the substrate 32 in the z-axis direction, starting with the thermoelectric conversion unit 33a. The thermoelectric conversion unit 33a is connected to the substrate 32. Thus, the four thermoelectric conversion units 33a to 33d form a multilayer body. In other words, the measuring system 1 further includes the multilayer body. The multilayer body is formed by layering multiple thermoelectric conversion elements 331 on the substrate 32 in the gradient direction. Such a configuration makes the size of the measuring system 1 in the in-plane direction smaller. Almost the same heat flow passes through the thermoelectric conversion units 33a to 33d forming the multilayer body.

In the present embodiment, the thermoelectric conversion elements 331 included in the thermoelectric conversion units 33a and 33c extend along the x-axis direction and are spontaneously magnetized in the y-axis direction. The thermoelectric conversion elements 331 of the thermoelectric conversion unit 33a and the thermoelectric conversion elements 331 of the thermoelectric conversion unit 33c are configured such that the directions of spontaneous magnetization thereof are opposite (e.g., anti-parallel). Thus, the thermoelectric conversion unit 33a and thermoelectric conversion unit 33c have opposite polarities. This allows the thermoelectric conversion units 33a and 33c to output electromotive forces in opposite directions on the basis of the same temperature gradient in the z-axis direction. The thermoelectric conversion units 33a and 33c are examples of a first thermoelectric conversion element, and the y-axis direction is an example of a first output direction. In other words, the multiple first thermoelectric elements are configured to output electromotive forces along the first output direction, which is one of the in-plane directions of the substrate 32, on the basis of the temperature gradient. The polarity of at least one of the first thermoelectric conversion elements is different from the polarity of at least one of the first thermoelectric conversion elements. Such a configuration, for example, eliminates the effect of an electromotive force based on a temperature gradient in the in-plane direction, thereby making the measuring system 1 more accurate.

In the present embodiment, the thermoelectric conversion elements 331 included in the thermoelectric conversion units 33b and 33d extend along an in-plane direction different from that of the thermoelectric conversion elements 331 included in the thermoelectric conversion units 33a and 33c and, specifically, along the y-axis direction and are spontaneously magnetized in the x-axis direction. The thermoelectric conversion elements 331 of the thermoelectric conversion unit 33b and the thermoelectric conversion elements 331 of the thermoelectric conversion unit 33d are configured such that the directions of spontaneous magnetization thereof are opposite (e.g., anti-parallel). Thus, the thermoelectric conversion unit 33b and thermoelectric conversion unit 33d have opposite polarities. This allows the thermoelectric conversion units 33b and 33d to output electromotive forces in opposite directions on the basis of the same temperature gradient in the z-axis direction. The thermoelectric conversion elements 331 included in the thermoelectric conversion units 33b and 33d are an example of a second thermoelectric conversion element, and the x-axis direction is an example of a second output direction. In other words, the thermoelectric conversion unit 33 includes the multiple second thermoelectric conversion elements. The second thermoelectric elements are configured to output electromotive forces along a second output direction, which is one of the in-plane directions of the substrate 32 and is different from the first output direction, on the basis of the temperature gradient. The polarity of at least one of the second thermoelectric conversion elements is different from the polarity of at least one of the second thermoelectric conversion elements. Such a configuration reduces the effect of the temperature gradients in the multiple in-plane directions. It can also be understood that the thermoelectric conversion units 33a and 33b constitute one thermoelectric conversion section, the thermoelectric conversion units 33c and 33d constitute one thermoelectric conversion section, and these thermoelectric conversion sections have different polarities. The first output direction and second output direction may be any directions as long as they are each along one of the in-plane directions, and do not have to be perpendicular to the z-axis direction (in other words, the gradient direction). The first output direction and second output direction do not have to be perpendicular to each other as long as they intersect each other. The number of layered thermoelectric conversion units 33 does not have to be four.

### 2. Another Example of Measuring System 1

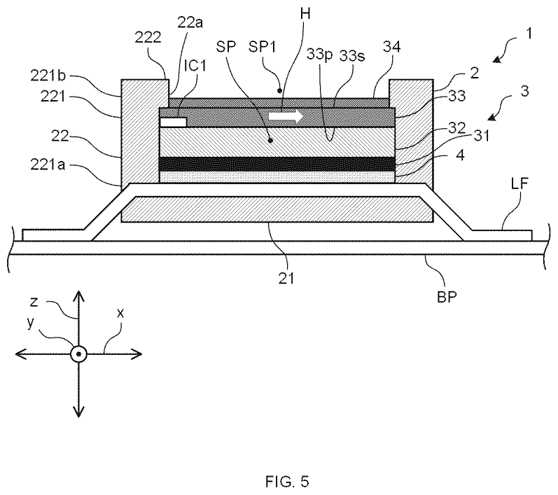

This section describes another example of the above measuring system 1. FIG. 5 is a diagram showing another example of the measuring system 1. The same components as those of the above measuring system 1 are given the same reference signs and therefore the description thereof may be omitted.

As shown in FIG. 5, the measuring system 1 according to the present embodiment may include a coil layer 4 in addition to the components of the measuring system 1 described in the preceding section. The coil layer 4 is configured to apply an external magnetic field H to the heat flow sensor 3 (specifically, the thermoelectric conversion unit 33). For example, the coil layer 4 applies the external magnetic field H such that the magnetization direction of the magnetic domain of the thermoelectric conversion unit 33 can be reversed. In other words, the coil layer 4 may be configured to apply the external magnetic field H to the thermoelectric conversion unit 33 such that the sign of an element based on the anomalous Nernst effect of the elements of thermoelectric tensor of the thermoelectric conversion unit 33 is reversed by the external magnetic field H. According to such a configuration, the external magnetic field H reverses the element of the thermoelectric tensor, thereby amplifying the intensity in the modulation frequency fm band of an electrical signal (the total electromotive force V1) outputted from the heat flow sensor 3. For example, the coil layer 4 may be disposed with respect to the thermoelectric conversion unit 33 such that the external magnetic field H applied to the thermoelectric conversion unit 33 is induced along the x-axis direction, which is an in-plane direction. According to such a configuration, a small in-plane magnetic field is induced to the thin film and thus the magnetic domain is easily modulated. This further amplifies the signal intensity in the modulation frequency band. In the present embodiment, the coil layer 4 is configured to apply the external magnetic field H along the x-axis direction, which is the magnetization direction of the magnetic domain of the thermoelectric conversion unit 33. While, in the present embodiment, the coil layer 4 is disposed between the bonding layer 31 and the substrate 32, this is not limiting. The coil layer 4 may be disposed in any position.

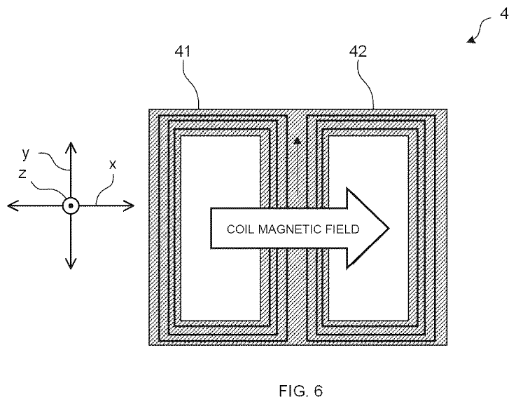

Next, an example configuration of the above coil layer 4 will be described. FIG. 6 is a plan view from the z-axis direction of the coil layer 4 incorporated in the heat flow sensor 3. The coil layer 4 according to the present embodiment is formed as a multilayer body layered on the first wall 21. As shown in FIG. 6, coil layer 4 includes a first coil 41 as a first magnetic field generation element and a second coil 42 as a second magnetic field generation element. The first coil 41 and second coil 42 are mounted on the substrate 32 as coil patterns layered in a square spiral shape along the z-axis direction. The first coil 41 and second coil 42 are configured to apply a magnetic field in the z-axis direction when a current is passed therethrough. The first coil 41 and second coil 42 are aligned along the x-axis direction, which is the magnetization direction of the thermoelectric conversion unit 33.

When the polarity of the first coil 41 and the polarity of the second coil 42 are opposite, magnetic field lines generated from the N pole of the first coil 41 extend toward the S pole of the second coil 42 and magnetic field lines generated from the N pole of the second coil 42 extend toward the S pole of the first coil 41. As a result, a circular external magnetic field H around the y-axis direction is formed. Thus, at least a portion of the external magnetic field H is induced to the thermoelectric conversion unit 33 along the x-axis direction, which is an in-plane direction of the thin film-shaped thermoelectric conversion unit 33. As seen above, defining the positional relationship between the first coil 41 and the second coil 42 and setting the polarities in accordance with the positional relationship is an example of generating a magnetic field on the basis of an input signal having a phase difference corresponding to the positional relationship between the first coil 41 and the second coil 42. Such a configuration realizes a signal processing system that is integral with the thermoelectric conversion unit 33 and is more compact. The first coil 41 and second coil 42 may have opposite chiralities. In this case, the first coil 41 and second coil 42 may be connected in series. According to such a configuration, when a current passed through the first coil 41 is transferred to the second coil 42, the polarities of the first coil 41 and second coil 42 are reversed. Thus, the control of the first coil 41 and second coil 42 is simplified.

The coil layer 4 may be formed such that its outer edge surrounds the first wall 21 when the substrate 32 is seen in a plan view from the z-axis direction. Such a configuration facilitates application of the external magnetic field H to the entire thermoelectric conversion unit 33 disposed on the substrate 32. The first coil 41 and second coil 42 may be disposed to be away from each other in the x-axis direction. Such a configuration facilitates application of the external magnetic field H along the y-axis direction to the thermoelectric conversion unit 33. The integrated circuit IC1 may be configured to control the driving mode of the coil layer 4.

The coil layer 4 does not have to be used to apply a magnetic field to the thermoelectric conversion unit 33. For example, the coil layer 4 may be used as a heater for high-frequency heating. Thus, for example, the temperature of the catalyst layer 34 can be maintained at or above the activation temperature at which a catalytic reaction is activated, resulting in an improvement in the accuracy of measurement of the target particles. The coil layer 4 may be controlled to maintain the temperature of the first surface 33p of the thermoelectric conversion unit 33 within a predetermined range. Such a configuration stabilizes the temperature of the first surface 33p of the thermoelectric conversion unit 33, thereby allowing for accurate estimation of the temperature of the second surface 33s from the electromotive force based on the heat flow.

### 3. Another Example of Measuring System 1

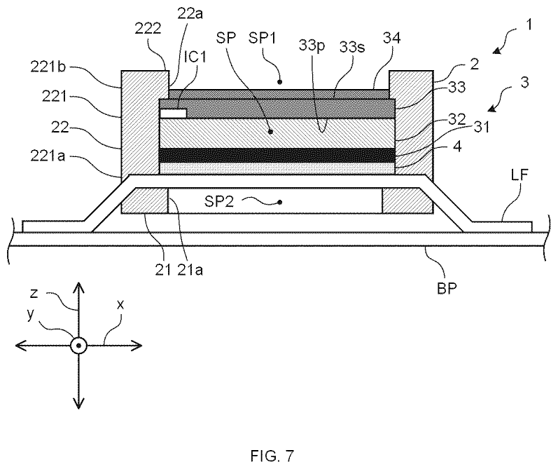

This section describes another example of the measuring system 1 described in section 2. The configuration of this example can also be applied to the measuring system 1 described in section 1. FIG. 7 is a diagram showing the configuration of another example of the measuring system 1.

As shown in FIG. 7, the first wall 21 of the measuring system 1 may further have an opening 21a. The opening 21a penetrates the first wall 21 in the z-axis direction. An opening space SP2 that connects the housing space SP and the outside is defined by the opening 21a. The coil layer 4 is exposed to the outside through the lead frame LF. Such a configuration releases heat accumulated in the coil layer 4 for applying a magnetic field, to the outside, thereby reducing the heat to be transferred from the coil layer 4 to the heat flow sensor 3. Thus, the contribution of the coil layer 4 to the measurement results of the heat flow sensor 3 is reduced, resulting in more accurate measurement of the heat flow.

The measuring system 1 according to the present embodiment does not have to include the coil layer 4. In this case, the bonding layer 31 is disposed only in the area where the substrate 32 and the first wall 21 contact each other. Thus, at least a portion of the substrate 32 is exposed through opening 21a, which allows the substrate 32 to directly exchange heat with the outside. This allows the outside to be used as a heat bath, thereby making the measuring system 1 a system that suppresses a reduction in the stability of output of the electromotive force and is more compact.

### 4. Another Example of Measuring System 1

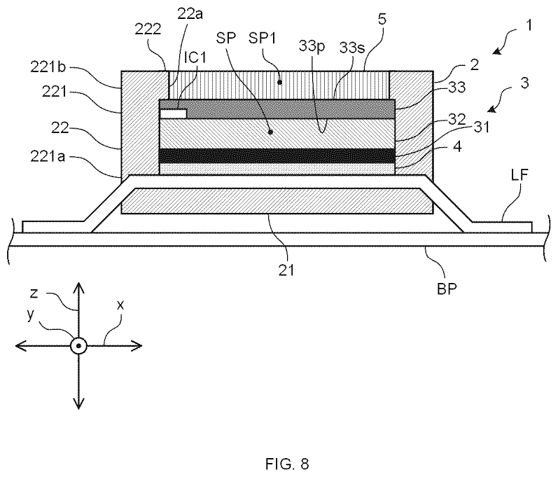

This section describes yet another example of the measuring system 1 described in section 2. The configuration of this example can also be applied to the measuring system 1 described in section 1 or 3. FIG. 8 is a diagram showing the configuration of yet another example of the measuring system 1.

As shown in FIG. 8, the measuring system 1 may further include a heat conductor 5. Note that the measuring system 1 shown in FIG. 8 does not include the catalyst layer 34. The heat conductor 5 is made of a material having high thermal conductivity, for example, a metal. For example, the heat conductor 5 is connected to the second surface 33s of the thermoelectric conversion unit 33 through the opening space SP1 defined by the opening 22a. An insulating film (not shown) is interposed between the heat conductor 5 and the thermoelectric conversion unit 33. Thus, the heat conductor 5 and thermoelectric conversion unit 33 are configured to exchange heat with them electrically insulated from each other. Such a configuration improves the efficiency of heat transfer to the thermoelectric conversion unit 33 and reduces the possibility that the thermoelectric conversion unit 33 can degrade due to its mechanical interference with the outside. In the present embodiment, the heat conductor 5 covers the entire opening space SP1. The heat conductor 5 is uniformly connected to the entire second surface 33S of the thermoelectric conversion unit 33. Thus, variations in the temperature distribution in the thermoelectric conversion unit 33 are reduced.

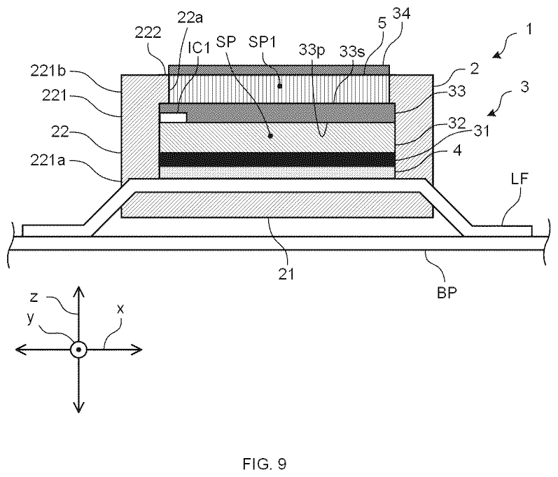

The measuring system 1 may further include a catalyst layer 34. FIG. 9 is a diagram showing another example of the measuring system 1 shown in FIG. 8. As shown in FIG. 9, the catalyst layer 34 is connected to an end opposite to an end connected to the second side 33s of the thermoelectric conversion unit section 33 of the ends of the heat conductor 5. In the present embodiment, the catalyst layer 34 is exposed to the outside of the opening space SP1. Such a configuration further facilitates contact of the catalyst layer 34 with the gas G1, thereby increasing the reactivity of the catalyst layer 34 and improving the accuracy of detection of the target particles included in the gas G1.

### [Others]

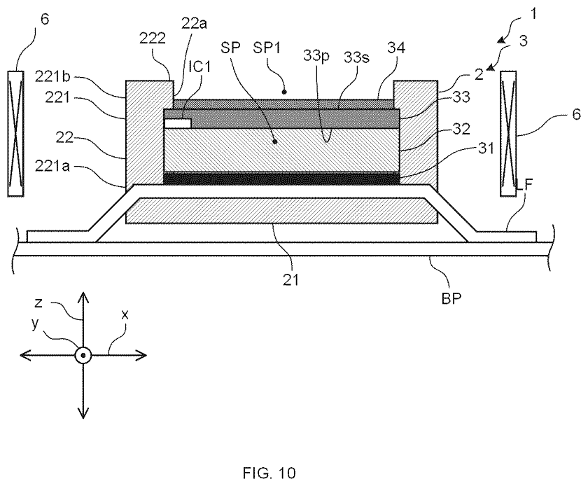

The coil layer 4 for applying the external magnetic field H does not have to be incorporated into the housing 2. FIG. 10 is a diagram showing an example of the measuring system 1 including magnetic field application units. As shown in FIG. 10, the measuring system 1 may include, for example, magnets 6 disposed outside the housing 2 as magnetic field application units for applying the external magnetic field H. The magnets 6 may be any type of magnets, such as permanent magnets, electromagnets, or coils as long as they are able to electrically or mechanically control the polarity of the external magnetic field H.

The opening 22a may be defined in any position as long as the thermoelectric conversion unit 33 can be exposed through the opening 22a. For example, the opening 22a may be defined to be oriented toward the wiring board BP. In other words, the measuring system 1 may be formed to be inverted in the z-axis direction toward the wiring board BP.

The lead frame LF does not have to penetrate the second wall 22 but may be formed to penetrate any position of the housing 2.

The integrated circuit IC1 may be disposed outside the housing 2, for example, on the wiring board BP.

The catalyst layer 34 may contain catalysts having different types of reactivity so that multiple types of target particles can be detected.

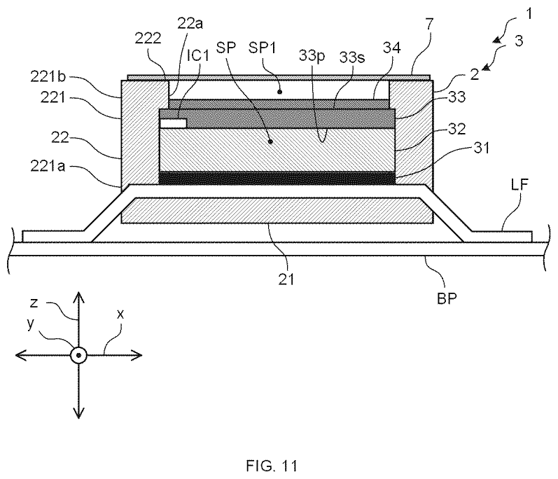

FIG. 11 is diagram showing an example configuration of the measuring system 1. As shown in FIG. 11, the measuring system 1 may include a filter 7 in addition to components similar to those of the measuring system 1 shown in FIG. 1. The filter 7 is disposed to cover at least a portion, for example, all of the opening 22a. The outer edge of the filter 7 is connected to, for example, the second end 221b of the peripheral wall 221. The filter 7 is, for example, a dust filter. Such a configuration suppresses a reduction in the performance of the measuring system 1 due to adherence of dust or the like to the thermoelectric conversion unit 33 or catalyst layer 34. The measuring system 1 may include, as the filter 7, a particle filter (e.g., a gas filter) configured to selectively transmit a fluid (e.g., a gas) containing the target particles that interact with the catalyst layer 34. Such a configuration allows the catalyst layer 34 to efficiently react to the target particles.

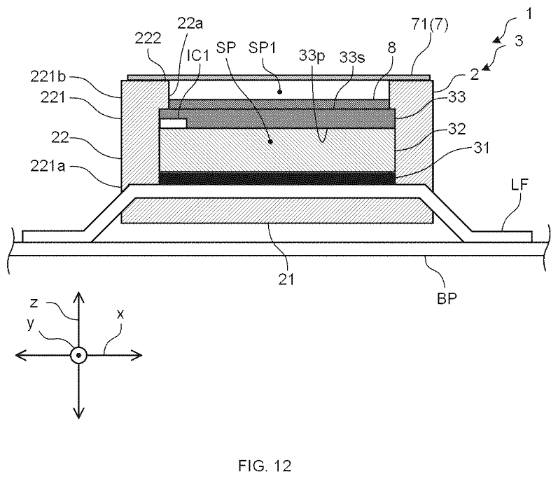

FIG. 12 is a diagram showing an example configuration of the measuring system 1 including an optical filter 71 as the filter 7. As shown in FIG. 12, the measuring system 1 may include the optical filter 71 as an example of the filter 7. The optical filter 71 is configured to selectively transmit light in a specific wavelength band. According to such a configuration, the electromotive force outputted from the thermoelectric conversion unit 33 is changed in accordance with the intensity or the like of the light transmitted through the optical filter 71. Thus, the measuring system 1 can be used to measure a quantity related to the light transmitted through the optical filter 71. In this case, the measuring system 1 may further include a light absorbing layer 8. The light absorbing layer 8 is configured to absorb the light in the specific wavelength band transmitted through the optical filter 71. For example, the light absorbing layer 8 is connected to the second surface 33s of the thermoelectric conversion unit 33 and is configured to exchange heat with the thermoelectric conversion unit 33 through the second surface 33s. The light absorbing layer 8 generates heat by absorbing the light transmitted through the optical filter 71. The generated heat is transferred from the light absorbing layer 8 to the thermoelectric conversion unit 33 through the second surface 33S, and the heat flow is reflected on the electromotive force. The measuring system 1 thus configured can be used to make measurements related to the light in the specific wavelength band. For this reason, the measuring system 1 can be made to function as, for example, a light measuring system. In particular, if a gas G1 is able to absorb this light, the electromotive force outputted from the thermoelectric conversion unit 33 is changed in accordance with the intensity of the light transmitted through the gas G1. For this reason, the measuring system 1 can be made to function as a system for selectively detecting the specific gas. The optical filter 71 may be disposed in place of the catalyst layer 34, or may be connected to the second surface 33s in parallel with the catalyst layer 34, or may be connected to the second surface 33s through the catalyst layer 34.

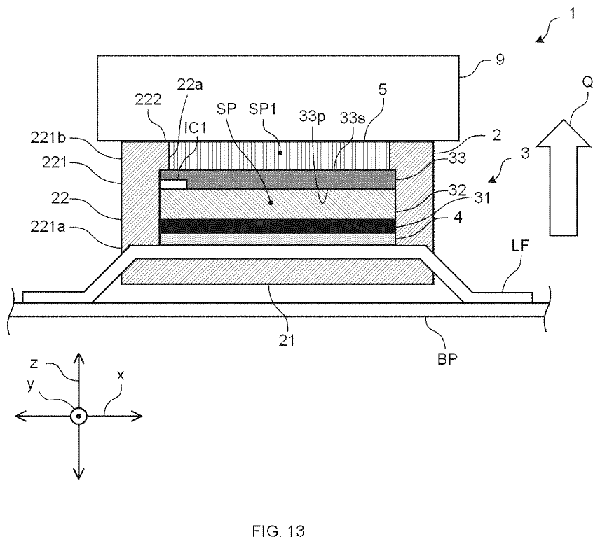

FIG. 13 is a diagram showing an example configuration of the measuring system 1. The measuring system 1 shown in FIG. 13 differs from the measuring system 1 shown in FIG. 8 in that it further includes a heat conductor 9. The heat conductor 9 is connected to the heat conductor 5 and is configured to exchange heat with the heat conductor 5. Thus, for example, heat Q is transferred between the wiring board BP and the heat conductor 9 through the thermoelectric conversion unit 33, and the transfer of the heat Q is detected as the electromotive force of thermoelectric conversion unit 33. For this reason, a quantity related to the heat exchanged with the wiring board BP can be measured as the electromotive force. The heat conductor 9 may be made of a material different from or identical to that of the heat conductor 5. The heat conductor 5 and heat conductor 9 may be integrated. Although the heat conductor 9 may be formed in any shape, it preferably covers the opening 22a from the z-axis direction. Such a configuration suppresses a reduction in the heat exchange efficiency due to the concentration of heat transferred to the heat conductor 9. The heat conductor 9 may be disposed such that the outer edge of the heat conductor 9 includes the outer edge of the second wall 22 when the measuring system 1 is seen in a plan view from the z-axis direction. Such a configuration further widens the heat absorbing/releasing portion, thereby further suppressing a reduction in the heat exchange efficiency. The heat conductor 9 is disposed to protrude in the z-axis direction from the second end 221b. More specifically, the heat conductor 9 may be a plate whose main surface has the z-axis direction along the second end 221b as its normal direction. The heat conductor 9 is electrically insulated from the thermoelectric conversion unit 33.

The measuring system may be provided in aspects below.
(1) A measuring system comprising: a heat flow sensor including: a substrate including electrical insulation properties, and a thermoelectric conversion unit disposed on the substrate, the thermoelectric conversion unit being configured to generate an electromotive force on the basis of a temperature gradient along a gradient direction that is a direction from the substrate toward the thermoelectric conversion unit; and a housing houses the heat flow sensor and includes: a first wall configured to face the substrate, and a second wall configured to cover the heat flow sensor by extending along the gradient direction from the first wall to and includes an opening, the opening configured to penetrate the second wall so that at least a portion of the thermoelectric conversion unit communicates with outside of the housing not through the substrate.

Such a configuration allows heat accumulated inside the housing to escape through the opening, thus improving stability of the electromotive force generated on the basis of heat exchange with the outside.
(2) The measuring system according to (1), wherein the opening is configured to penetrate the housing along the gradient direction with respect to the thermoelectric conversion unit.

Such a configuration promotes heat transfer in the gradient direction and further improves the stability of the electromotive force.
(3) The measuring system according to (1) or (2), wherein the opening is configured to overlap at least a portion of the thermoelectric conversion unit when the thermoelectric conversion unit is seen in a plan view from the gradient direction.

According to such a configuration, thermal convection promotes the contact between the thermoelectric conversion unit and the outside air.
(4) The measuring system according to any one of the (1) to (3), further comprising an interaction portion configured to absorb or generate heat due to a change in a bonding state thereof caused when contacted by target particles and to exchange the absorbed or generated heat with the thermoelectric conversion unit, the interaction portion being configured to be exposed through the opening when the thermoelectric conversion unit is seen in a plan view from the gradient direction.

When the interaction portion thus configured takes in the outside air through the opening, the target particles contained in the outside air and the interaction portion react with each other. For this reason, a quantity related to the reaction of the target particles can be obtained as the electromotive force on the basis of the resulting heat of reaction.
(5) The measuring system according to any one of (1) to (4), wherein: the second wall includes a peripheral wall configured to extend along the gradient direction from a periphery of the first wall, the measuring system further comprising a conductor electrically connected to the thermoelectric conversion unit through the substrate and penetrates the peripheral wall so that the electromotive force is transferred to the outside of the housing.

Such a configuration makes the thickness of the measuring system in the gradient direction smaller.
(6) The measuring system according to any one of (1) to (5), wherein the second wall includes: a peripheral wall configured to extend along the gradient direction from a periphery of the first wall, and an end wall: connected to an end different from an end connected to the first wall portion of ends of the peripheral wall, and configured to cover a portion of the thermoelectric conversion unit not through the substrate or a substrate different from the substrate.

According to such a configuration, heat exchange through the opening by the thermoelectric conversion unit 33 is performed not through the substrate or the like. This improves the efficiency of heat transfer from the outside to the thermoelectric conversion unit, thereby increasing the response speed of the measuring system.
(7) The measuring system according to any one of (1) to (6), further comprising an integrated circuit configured to acquire the electromotive force, the integrated circuit being: configured to perform predetermined signal processing on the basis of at least the electromotive force outputted from the thermoelectric conversion unit, and disposed on the substrate together with the thermoelectric conversion unit.

Such a configuration allows the measuring system to perform a series of processes from generation of the electromotive force by the thermoelectric conversion unit to signal processing.
(8) The measuring system according to any one of (1) to (7), wherein the thermoelectric conversion unit is configured to generate the electromotive force on the basis of the anomalous Nernst effect.

Such a configuration makes the size of the measuring system in the gradient direction more compact than that of a measuring system using Seebeck elements.

Of course, these aspects are not limiting.

Finally, while the various embodiments according to the present disclosure have been described above, the embodiments are only illustrative and are not intended to limit the scope of the invention.

The novel embodiments can be carried out in other various forms, and various omissions, replacements, or changes can be made thereto without departing from the gist of the invention. The embodiments and modifications thereof are included in the scope and gist of the present invention, as well as included in the scope of the invention set forth in the claims and equivalents thereof.

The following aspects should also be noted.

Conventional heat flux sensors are heat flux sensors using the Seebeck effect. The housing of such sensors using the Seebeck effect is formed to be sturdy for protection but has large heat capacity and thermal resistance. These sensors having large thermal resistance and heat capacity block the heat flow path and therefore have difficulty in correctly measuring the heat flow.

For this reason, in a device according to the present embodiment and a system using the device, for example, a heat flow sensor film having high thermal conductivity that generates the anomalous Nernst effect is disposed on a substrate having good thermal conductivity, and the sensor substrate is housed in a housing having high insulation properties and thermal conductivity. Such a configuration allows for more correct measurement of the heat flow.

A heat flow sensor according to the present embodiment (an example of the device) is preferably a thin film-type heat flow sensor based on the anomalous Nernst effect in terms of the responsiveness. The elements (i.e., the thermoelectric conversion elements) of the heat flow sensor (i.e., the thermoelectric conversion device) may be made of a compound that exhibits anomalous Nernstian effects. For example, the elements may be made of a topological ferromagnetic material or topological antiferromagnetic material called Weyl semimetal, a ferrimagnetic material, or a combination thereof. The topological ferromagnetic material may be a metal with a composition Co₂TX (where X represents any one of Si, Ge, Sn, Al, and Ga), such as Co₂MnGa, or may be an alloy of a known topological ferromagnetic material, such as a metal with a composition formula Fₑ3X (where X represents a typical element such as Al or Ga, or a transition element) (a stoichiometric or off-stoichiometric composition). The topological antiferromagnetic material may be a known topological antiferromagnetic material such as Mn₃X (where X represents one or more elements selected from Sn, Ge, Ga, Pt, Ir, and Rh, or a compound of these). The alloy containing the topological ferromagnetic material or topological antiferromagnetic material does not necessarily have to have a stoichiometric composition ratio as described above. The alloy may have any composition ratio as long as it has a partially stoichiometric structure. The compound constituting the elements may consist of, for example, an alloy containing a transition metal, and the alloy may be a compound that has a crystal structure with Kagome lattice planes made of a transition metal and exhibits the anomalous Nernstian effect. The ferrimagnetic material may be any type of ferrimagnetic material as long as it generates the anomalous Nernst effect. The structure of the elements is not limited to a particular structure, and any known structure may be used. The elements may be formed by sputtering, evaporation, MBE, plating, sintering, printing, pasting, or the like. The heat flow sensor according to the present embodiment may be configured not only to measure heat, but also to detect light, a chemical, or the like.

In the heat flow sensor according to the present embodiment, the heat flow sensor film (a circuit consisting of the thermoelectric conversion elements) is formed on the substrate, and the substrate is bonded to the housing. The top surface of the heat flow sensor film may also be bonded to the housing. The material of the bonding film or housing is preferably a material having relatively low thermal resistance and heat capacity. For example, the material of the housing may be a metal, carbon, or the like.

The heat flow sensor film may be a multilayer film, or may include a magnet layer (hard layer), or may include a coil layer, or may be a film formed by inserting an insulating layer and stacking a circuit of the thermoelectric conversion elements, or may be any combination of these. To cancel out the Seebeck effect, which acts as the noise of the anomalous Nernst effect, multiple (preferably, four) heat flow sensors having different polarities may be formed on a flat surface or in the shape of a multilayer film. For example, the sum of signals A, B, C, and D shown in the diagrams cancels out the Seebeck effect so that the anomalous Nernst effect (a heat flow in the z direction) can be extracted. A and D can detect a heat flow in the x-direction from the Seebeck effect, and C and B can detect a heat flow in the y-direction from the Seebeck effect. The order of the diagrams may be any order. A thin bonding layer may be provided between the sensor film and the substrate. The bonding layer may be made of any material as long as it has low thermal resistance. Preferably, the housing has low thermal resistance.

To make more accurate measurements, an IC for signal processing that includes an MUX, an amplifier, an ADC, a processor, a DSP, memory, a communication function, and the like may be provided. In this case, the substrate 32 may be, for example, a chip that incorporates an LSI (large-scale integrated circuit) made of Si or the like, or may be an insulating film made of polyamide or the like, a flexible circuit board, a printed circuit board, a sapphire substrate, an Al board, a Cu board, an MgO board, or a substrate made of GaN, SiC, SiO₂/Si, Ta₂O₅/Ta, Al₂O₃, Al₂O₃/Al, SiN, Ti, TiO₂/Ti, CuO/Cu, Ga₂O₃, GaAs, InAs, InGaAs, InSb, or the like or a composite or the like thereof and having good thermal conductivity on which an IC is mounted, or may be any combination thereof. The terminals may be disposed on a flexible circuit board. These structures are not limiting.

An opening may be formed in an upper portion or lower portion of the heat flow sensor so that the heat flow sensor communicates with the outside and thus the thermal resistance is reduced. The opening may be a physical opening, or the heat flow sensor may be connected to a member having low thermal resistance. The PKG (package) of the IC may be a PKG shown in the diagram or a package such as a WLCSP.

A modification of the present embodiment will be described. For example, by providing a film or the like capable of absorbing electromagnetic radiation such as light on the heat flow sensor, electromagnetic radiation may be detected. By further providing an optical filter, only electromagnetic radiation (light) in a selected wavelength band may be detected. Thus, the selectivity can be increased. Further, by applying or providing a substance that reacts to or adsorbs a gas, liquid, or solution on the heat flow sensor, the gas or the like that reacts with the substance can be detected. If the above substance is thermally coupled to the heat flow sensor, it does not have to be provided directly on the heat flow sensor.

Another modification of the present embodiment will be described. A coil for generating a magnetic field for modulating the heat flow sensor or heat for heating the catalyst may be disposed inside the LSI or in any other layer. Since such a coil transmits heat, there is no problem in making measurements. The coil may be disposed in any position as long as the position has good heat conductivity. The application of the heat flow sensor is not limited to a particular application. The heat flow sensor only has to be a heat flow sensor based on the anomalous Nernst effect and does not have to detect electromagnetic radiation or substance.

1. A measuring system comprising:
a heat flow sensor including:
a substrate including electrical insulation properties, and
a thermoelectric conversion unit, implemented by circuitry, disposed on the substrate, the thermoelectric conversion unit being configured to generate an electromotive force on the basis of a temperature gradient along a gradient direction that is a direction from the substrate toward the thermoelectric conversion unit; and
a housing configured to house the heat flow sensor and includes:
a first wall configured to face the substrate, and
a second wall configured to cover the heat flow sensor by extending along the gradient direction from the first wall, and includes an opening, the opening configured to penetrate the second wall so that at least a portion of the thermoelectric conversion unit communicates with outside of the housing not through the substrate.

2. The measuring system according to claim 1, wherein
the opening is configured to penetrate the housing along the gradient direction with respect to the thermoelectric conversion unit.

3. The measuring system according to claim 1, wherein
the opening is configured to overlap at least a portion of the thermoelectric conversion unit when the thermoelectric conversion unit is seen in a plan view from the gradient direction.

4. The measuring system according to claim 1, further comprising
an interaction portion configured to absorb or generate heat due to a change in a bonding state thereof caused when contacted by target particles and to exchange the absorbed or generated heat with the thermoelectric conversion unit,
the interaction portion being configured to be exposed through the opening when the thermoelectric conversion unit is seen in a plan view from the gradient direction.

5. The measuring system according to claim 1, wherein:
the second wall includes a peripheral wall configured to extend along the gradient direction from a periphery of the first wall,
the measuring system further comprising
a conductor electrically connected to the thermoelectric conversion unit through the substrate and configured to penetrate the peripheral wall so that the electromotive force is transferred to the outside of the housing.

6. The measuring system according to claim 1, wherein
the second wall includes:
a peripheral wall configured to extend along the gradient direction from a periphery of the first wall, and
an end wall:
connected to an end different from an end connected to the first wall of ends of the peripheral wall, and
configured to cover a portion of the thermoelectric conversion unit not through the substrate or a substrate different from the substrate.

7. The measuring system according to claim 1, further comprising
an integrated circuit configured to acquire the electromotive force,
the integrated circuit being:
configured to perform predetermined signal processing on the basis of at least the electromotive force outputted from the thermoelectric conversion unit, and
disposed on the substrate together with the thermoelectric conversion unit.

8. The measuring system according to claim 1, wherein
the thermoelectric conversion unit is configured to generate the electromotive force on the basis of the anomalous Nernst effect.
